(19) United States
(12) Patent Application Publication
(10) Pub. No.: US 2020/0185269 A1
(43) Pub. Date: Jun. 11, 2020

(54) SELF-ALIGNED LITHO-ETCH DOUBLE PATTERNING

(71) Applicant: INTERNATIONAL BUSINESS MACHINES CORPORATION, Armonk, NY (US)

(72) Inventors: Hsueh-Chung Chen, Cohoes, NY (US); Yongan Xu, Niskayuna, NY (US); Yann Mignot, Slingerlands, NY (US); Jie Yang, Clifton Park, NY (US)

(21) Appl. No.: 16/216,169

(22) Filed: Dec. 11, 2018

(51) Int. Cl. H01L 21/768; H01L 21/311; H01L 21/033

(52) U.S. Cl. CPC H01L 21/76816; H01L 21/31144; H01L 21/0332; H01L 21/76879; H01L 21/0337; H01L 21/76897

(57) ABSTRACT

A mechanism for preparing a wafer and/or substrate is disclosed. A plurality of mandrel lines are etched via a mandrel mask. The mandrel lines are separated by spaces. Spin-on glass (SOG) is deposited to backfill the spaces between the mandrel lines. A non-mandrel mask is employed to etch spaces from the SOG in between the mandrel lines to create non-mandrel lines. The mandrel lines and the non-mandrel lines can then be replaced with a conductive material.

### BACKGROUND

The present disclosure relates to the field of semiconductor fabrication. Semiconductor fabrication processes endeavor to include more transistors in smaller areas of a semiconductor wafer to allow for more complex processes in a finalized microchip. This, in turn, results in shrinking circuit components to the extent possible given the limitations of manufacturing technologies. Lithography processes employ masks to controllably etch semiconductors to create circuits. However, machine precision places certain lower size limits on the size of openings and relative distance between openings in such masks. This may limit how small a final structure on a chip can be. In order to mitigate such issues, multi-patterning technologies, such as Self Aligned Double Patterning (SADP), employ multiple masks and perform multiple etches in sequence to create smaller structures. SADP includes certain limitations. For example, in SADP structures associated with one mask have certain size and position correlations relative to structures associated with another mask. Such correlations limit the flexibility of the process to accept circuit designs. Such correlations may also result in significant numbers of so called dummy traces that do no support circuit functionality and yet create significant parasitic capacitances that may impair circuit functionality. In addition, SADP is a complicated process that generally employs three or four masks to achieve a finalized circuit.

### SUMMARY

Aspects of the present disclosure provide for a wafer prepared by a process. The process comprises etching a plurality of mandrel lines via a mandrel mask, the mandrel lines separated by spaces. Spin-on glass (SOG) is deposited to backfill the spaces between the mandrel lines. A non-mandrel mask is employed to etch the SOG from the spaces between the mandrel lines to create non-mandrel lines. The mandrel lines and the non-mandrel lines are replaced with a conductive material. By etching the non-mandrel lines in the SOG, the non-mandrel lines can be positioned independently of the mandrel lines as desired instead of following the mandrel lines. Accordingly, dummy traces can be omitted, where a dummy trace is a conductive trace that is not employed for circuit components, and yet creates parasitic capacitances. Hence, this process reduces parasitic capacitance. Further, this process employs two extreme ultraviolet (EUV) masks instead of three to four as employed when SOG is not used. This process also reduces the area employed to create a sea of wires, and hence increases scalability of the design.

In any of the preceding aspects, the process can further comprise depositing spacers around the mandrel lines prior to depositing the SOG. The spacers guide the deposition of the SOG to support etching the non-mandrel lines.

In any of the preceding aspects, the non-mandrel lines and the mandrel lines can extend across the wafer along a first axis. Lengths and positions of the non-mandrel lines along the first axis can be independent of lengths and positions of mandrel lines along the first axis.

In any of the preceding aspects, etching the SOG via the non-mandrel mask can create non-mandrel lines that omit dummy traces.

In any of the preceding aspects, the process can further comprise performing an etch-back on the SOG, prior to etching the SOG, to expose at least some of the mandrel lines.

In any of the preceding aspects, gaps can be created in the mandrel lines by the non-mandrel mask.

In any of the preceding aspects, gaps can created in the mandrel lines by the mandrel mask prior to creating the non-mandrel lines.

In any of the preceding aspects, the mandrel lines and the non-mandrel lines can include a width along the second axis of eighty nanometers or less. Hence the process can be employed to create extremely small structures on a wafer.

Other aspects of the present disclosure provide for a method comprising etching a plurality of mandrel lines via a mandrel mask, the mandrel lines separated by a space. SOG is deposited to backfill the spaces between the mandrel lines. A non-mandrel mask is employed to etch the SOG from the spaces between the mandrel lines to create non-mandrel lines. The mandrel lines and the non-mandrel lines are replaced with a conductive material. By etching the non-mandrel lines in the SOG, the non-mandrel lines can be positioned independently of the mandrel lines as desired instead of following the mandrel lines. Accordingly, dummy traces can be omitted, where a dummy trace is a conductive trace that is not employed for circuit components, and yet creates parasitic capacitances. Hence, this process reduces parasitic capacitance. Further, this process employs two EUV masks instead of three to four as employed when SOG is not used. This process also reduces the area employed to create a sea of wires, and hence increases scalability of the design.

In any of the preceding aspects, the method can further comprise depositing spacers around the mandrel lines prior to depositing the SOG. The spacers can guide the deposition of the SOG to support etching the non-mandrel lines.

In any of the preceding aspects, the non-mandrel lines and the mandrel lines can extend across a wafer along a first axis. A length and position of the non-mandrel lines along the first axis can be independent of a length and position of mandrel lines along the first axis.

In any of the preceding aspects, etching the SOG via the non-mandrel mask can create non-mandrel lines that omit dummy traces.

In any of the preceding aspects, the method can further comprise performing an etch-back on the SOG, prior to etching the SOG, to expose at least some of the mandrel lines.

In any of the preceding aspects, gaps can be created in the mandrel lines by the non-mandrel mask.

In any of the preceding aspects, gaps can be created in the mandrel lines by the mandrel mask prior to creating the non-mandrel lines.

In any of the preceding aspects, the mandrel lines and the non-mandrel lines can include a width along the second axis of eighty nanometers or less. Hence the process can be employed to create extremely small structures on a wafer.

Other aspects of the present disclosure provide for a wafer comprising a substrate. A plurality of mandrel line channels of conductive material extend across the substrate along a first axis. The mandrel line channels are separated by spaces along a second axis perpendicular to the first axis. A plurality of non-mandrel line channels of conductive material extend across the substrate along a first axis. The lengths and positions of the non-mandrel line channels along the first axis are independent of lengths and positions of mandrel line channels along the first axis. By etching the non-mandrel line channels in the SOG, the non-mandrel line channels can be positioned independently of the mandrel line channels as desired instead of following the mandrel line channels. Accordingly, dummy traces can be omitted, where a dummy trace is a conductive trace that is not employed for circuit components, and yet creates parasitic capacitances. Hence, this process reduces parasitic capacitance. Further, this process employs two EUV masks instead of three to four as employed when SOG is not used. This process also reduces the area employed to create a sea of wires, and hence increases scalability of the design.

In any of the preceding aspects, the mandrel line channels can omit dummy traces uncoupled to operational components.

In any of the preceding aspects, the non-mandrel line channels can omit dummy traces uncoupled to operational components.

In any of the preceding aspects, the mandrel line channels and the non-mandrel line channels can include a width along the second axis of eighty nanometers or less. Hence the process can be employed to create extremely small structures on a wafer.

### BRIEF DESCRIPTION OF THE DRAWINGS

FIG. 1A is a top view of an example substrate including mandrel lines upon application of a mandrel pattern mask.

FIG. 1B is a top view of the example substrate including mandrel lines and non-mandrel lines upon application of a non-mandrel pattern mask.

FIGS. 2A-2B are a top view and a side view, respectively of a substrate including a film stack during an example manufacturing process.

FIGS. 3A-3B are a top view and a side view, respectively, of the substrate after lithographic etching via a mandrel pattern mask during the example manufacturing process.

FIGS. 4A-4B are a top view and a side view, respectively, of the substrate after spacer deposition during the example manufacturing process.

FIGS. 5A-5B are a top view and a side view, respectively, of the substrate after spin-on glass (SOG) backfill during the example manufacturing process.

FIGS. 6A-5B are a top view and a side view, respectively, of the substrate after SOG etch-back during the example manufacturing process.

FIGS. 7A-7B are a top view and a side view, respectively, of the substrate after lithographic etching via a non-mandrel pattern mask during the example manufacturing process.

FIGS. 8A-8B are a top view and a side view, respectively, of the substrate after non-mandrel removal during the example manufacturing process.

FIGS. 9A-9B are a top view and a side view, respectively, of the substrate after mandrel removal during the example manufacturing process.

FIGS. 10A-10B are a top view and a side view, respectively, of the substrate after Silicon Nitride (SiN) hard mask etching during the example manufacturing process.

FIGS. 11A-11B are a top view and a side view, respectively, of the substrate after Titanium Nitride (TiN) hard mask etching during the example manufacturing process.

FIGS. 12A-12B are a top view and a side view, respectively, of the substrate after dielectric etching during the example manufacturing process.

FIGS. 13A-13B are a top view and a side view, respectively, of the substrate after metallization during the example manufacturing process.

FIG. 14A is a top view of a second example substrate including mandrel lines upon application of a mandrel pattern mask.

FIG. 14B is a top view of the second example substrate including mandrel lines and non-mandrel lines upon application of a non-mandrel pattern mask.

FIGS. 15A-15B are a top view and a side view, respectively of a substrate including a film stack during a second example manufacturing process.

FIGS. 16A-16B are a top view and a side view, respectively, of the substrate after lithographic etching via a mandrel pattern mask during the second example manufacturing process.

FIGS. 17A-17B are a top view and a side view, respectively, of the substrate after spacer deposition during the second example manufacturing process.

FIGS. 18A-18B are a top view and a side view, respectively, of the substrate after SOG backfill during the second example manufacturing process.

FIGS. 19A-19B are a top view and a side view, respectively, of the substrate after SOG etch-back during the second example manufacturing process.

FIGS. 20A-20B are a top view and a side view, respectively, of the substrate after lithographic etching via a non-mandrel pattern mask during the second example manufacturing process.

FIGS. 21A-21B are a top view and a side view, respectively, of the substrate after non-mandrel removal during the second example manufacturing process.

FIGS. 22A-22B are a top view and a side view, respectively, of the substrate after mandrel removal during the second example manufacturing process.

FIGS. 23A-23B are a top view and a side view, respectively, of the substrate after SiN hard mask etching during the second example manufacturing process.

FIGS. 24A-24B are a top view and a side view, respectively, of the substrate after TiN hard mask etching during the second example manufacturing process.

FIGS. 25A-25B are a top view and a side view, respectively, of the substrate after dielectric etching during the second example manufacturing process.

FIGS. 26A-26B are a top view and a side view, respectively, of the substrate after metallization during the second example manufacturing process.

FIG. 27 is a flowchart of an example method of manufacturing a wafer in accordance with various embodiments.

### DETAILED DESCRIPTION

The present disclosure relates specifically to the use of SADP and similar multiple patterning technologies to create a sea of wires on a wafer. Such wires can be used to connect operational components on a final chip. As used herein, an operational component is a passive or an active component employed to condition and/or alter a signal on a microchip to support an intended functionality of the microchip (e.g., transistors, capacitors, resistors, etc.) SADP creates a multiplicity of wires by generating a set of mandrel lines, and then generating non-mandrel lines that are positioned based on the mandrel lines. A mandrel is an object used to shape other objects in a manufacturing process. A non-mandrel is an object shaped by a mandrel. Specifically, SADP employs a mandrel pattern to generate mandrel lines, a mandrel cut pattern to shape the mandrel lines (e.g., create gaps), a non-mandrel pattern to position non-mandrel lines between the mandrel lines, and a non-mandrel cut pattern to shape the non-mandrel lines (e.g., create gaps). This results in the use of four extreme ultraviolet (EUV) masks. Further, the mandrel lines define the shape of the non-mandrel lines, and hence both lines are the same length in SADP. This may cause some lines to be longer than necessary for a corresponding circuit design. Further, this may result in the creation of dummy traces that increase parasitic capacitances and are not used to operate the circuit. In addition, this approach deposits spacer material around the mandrel, which is employed to define the non-mandrel. When breaks occur in the spacer material during manufacturing, a non-mandrel line can be shorted to a mandrel line, which may cause undefined errors in the final fabricated circuit.

Disclosed herein are example embodiments of a Self-Aligned Litho-Etch Double Patterning (SALEDP) process. The SALEDP process creates non-mandrel lines with lengths that are independent of mandrel line lengths. This may provide greater design flexibility while mitigating the mandrel to non-mandrel shorting problem. Further, this process omits portions of the mandrel and/or non-mandrel lines that are used only for/as a consequence of shaping. This results in omitting dummy traces, which reduces lateral parasitic capacitance between lines by about seventy three percent. This may also remove the need for a post process to remove dummy traces to support circuit functionality. In addition, omitting portions of the lines that are employed only for shaping reduces the area of the sea of wires, and hence the minimum cut size on the wafer, which in turn enables further area scaling (e.g., allowing more functional material to fit on the wafer). The disclosed examples also employ two EUV masks instead of four, which reduces manufacturing complexity/cost. In the disclosed SALEDP process, mandrel lines are etched from a film stack on a wafer via a mandrel mask with a mandrel pattern. Spacer material is deposited around the mandrel lines. Spin-on glass (SOG) is then employed to backfill the space between the spacers. The SOG is etched down to reveal the mandrel lines. A non-mandrel mask can then be used to etch non-mandrel lines from the SOG. Since the non-mandrel lines are etched from a material (e.g., the SOG) the non-mandrel lines can be etched to lengths that are different than the mandrel lines. As such, the mandrel and non-mandrel lines can be of independent lengths, and the mandrel lines do not need to be artificially extended to support creation of the non-mandrel lines. Further, etching the mandrel lines and non-mandrel lines independently allows for omission of dummy traces, associated parasitic capacitances, and shorting issues. In one example the mandrel lines are of equal length after the mandrel mask, and then are cut into the final shape by the non-mandrel mask. In another example, the mandrel lines are cut into the final shape by the mandrel mask, which omits dummy mandrel sections before the non-mandrel lines are placed. In either case, channels from the mandrel lines and the non-mandrel lines are replaced by metal on a dielectric substrate to create the final sea of wires.

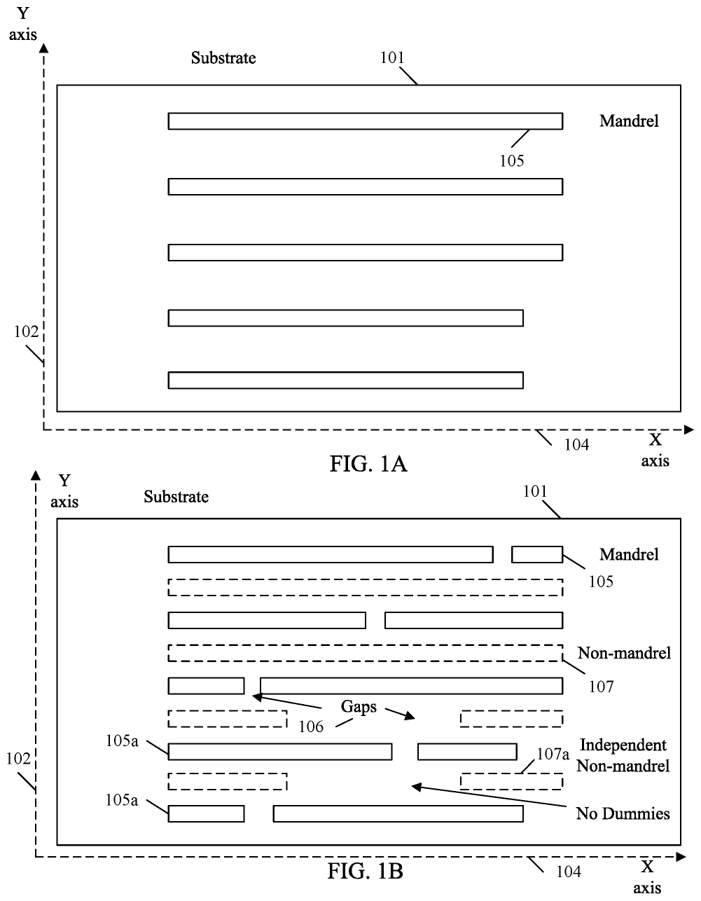

FIG. 1A is a top view of an example substrate 101 including mandrel lines 105 upon application of a mandrel pattern mask. The substrate is an underlying layer in a wafer used as a base for circuit structures. In this case, the substrate 101 is a base for a sea of conductive wires. Hence, the substrate 101 under the sea of wires includes an insulator to prevent/mitigate shorts between wires. The portion of the substrate 101 that contains active/passive electrical components powered by the sea of wires may include silicon (Si), Si on insulator (SOI), and/or other semi-conductive materials. The substrate 101 is depicted relative to a y axis 102 and an x axis 104 for clarity of discussion.

The substrate 101 contains a plurality of mandrel lines 105. The mandrel lines 105 contain temporary material that is replaced with conductive material, such as copper, gold, etc., upon completion of the manufacturing process. Hence, the mandrel lines 105 become the conductive material implementing a portion of the sea of wires over the course of the manufacturing process. The mandrel lines 105 extend across the substrate 101 along the x axis 104 (a first axis). Hence, the mandrel lines 105 contain a length along the x axis 104 and a width along the y axis 102 (a second axis). The mandrel lines 105 define the general position of non-mandrel lines along the y axis 102. Hence, the mandrel lines 105 are separated by spaces along the y axis 102, which is perpendicular to the x axis 104. The mandrel lines 105 are created by a lithographic process. For example, a mandrel mask is positioned over the substrate 101. An etching compound, such as a liquid etching solution (a wet etch) or a plasma reactive gas (a dry etch), can be applied to the substrate 101. The etching compound etches the mandrel lines 105 from the substrate 101 in areas exposed by the mask, but leave areas covered by the mask unchanged. For example, an EUV mask, a plasma reactive gas, and a laser may be employed when etching the mandrel lines 105.

FIG. 1B is a top view of the example substrate 101 including mandrel lines 105 and non-mandrel lines 107 upon application of a non-mandrel pattern mask. The mandrel lines 105 are depicted in solid lines and the non-mandrel lines 107 are depicted as dashed lines for purposes of clarity.

As shown, the substrate 101 includes a plurality of non-mandrel lines 107, which are replaced which act as placeholders for conductive material in a manner similar to the mandrel lines 105. The non-mandrel lines 107 extending across the substrate 101 along an x axis 104 and contain lengths and widths measured with respect to the x axis 104 and y axis 102 respectively. The non-mandrel lines 107 are positioned in the spaces between the mandrel lines 105 along the y axis 102. The non-mandrel lines 107 are etched onto the substrate 101 via a non-mandrel mask. In the example shown, the mandrel lines 105 are initially solid lines upon application of the mandrel mask. The non-mandrel mask then etches any desired gaps 106 into the mandrel lines 105 in addition to etching the non-mandrel lines 107 (along with any desired gaps 106 in the non-mandrel lines). Such gaps 106 are employed to segregate portions of conductive material when different sections of a common non-mandrel line 107 of mandrel line 105 form a different parts of a circuit that are not designed to be electrically shorted together.

The process employed to etch substrate 101 allows the lengths and positions of the non-mandrel lines 107 along the x axis 104 to be independent of lengths and positions of the mandrel lines 105 along the x axis 104. As shown, non-mandrel line 107a extends beyond mandrel lines 105a, and is hence independent of the length of the mandrel lines 105a. For example, in an SADP process, the mandrel lines 105a would be employed to define the area of the non-mandrel line 107a, and hence such a process would be incapable of allowing non-mandrel line 107a to extend beyond mandrel lines 105a in this manner. However, the disclosed SALEDP process etches the non-mandrel line 107a into SOG, which allows for such independence in length and position between the mandrel lines 105 and adjacent non-mandrel lines 107. Such independence allows for greater design flexibility and area scaling.

Further, the disclosed SALEDP process allows both the mandrel lines 105 and the non-mandrel line 107 to omit dummy traces uncoupled to operational components. As shown by non-mandrel line 107a, no line, and hence no conductive material, is placed between the two portions of non-mandrel line 107a. In an SADP process, the non-mandrel lines 107 fill the spaces between the mandrel lines 105, and hence leave dummy traces in such positions. Since the disclosed SALEDP process etches the non-mandrel line 107a into SOG, the non-mandrel line 107a can terminate without being bounded by mandrel line 105a material. This allows for the omission of the dummy traces, and hence allows for the omission of associated parasitic capacitances. This may reduce parasitic capacitances by about seventy three percent and alleviate any need to remove such dummy traces by a subsequent manufacturing process. Also, since the non-mandrel lines 107 are etched into the SOG instead of being bounded by the mandrel lines 105, the non-mandrel lines 107 do not short to the mandrel lines 105 in the event of a failure of spacer material around the mandrel lines 105. Further, as shown, a sea of wires including mandrel lines 105 and non-mandrel lines 107 can be created by employing two EUV masks (e.g., a mandrel mask and a non-mandrel mask) instead of three to four EUV masks in an SADP process.

It should be noted that the SALEDP process allows for the creation of very small wires. For example, the mandrel lines 105 and/or the non-mandrel lines 107 may include a width along the y axis 102, and hence a corresponding pin pitch, of eighty nanometers (nm) or less. Specifically, the SALEDP process can be employed for a fourteen nm process, a ten nm process, a seven nm process, etc. Accordingly, the width along the y axis 102 of mandrel lines 105 and/or the non-mandrel lines 107 can be fourteen nm, ten nm, seven nm, etc. Further, the spacing between the mandrel lines 105 and the non-mandrel lines 107 along the y axis 102 can be eighty nm or less (e.g., fourteen nm, ten nm, seven nm, etc.)

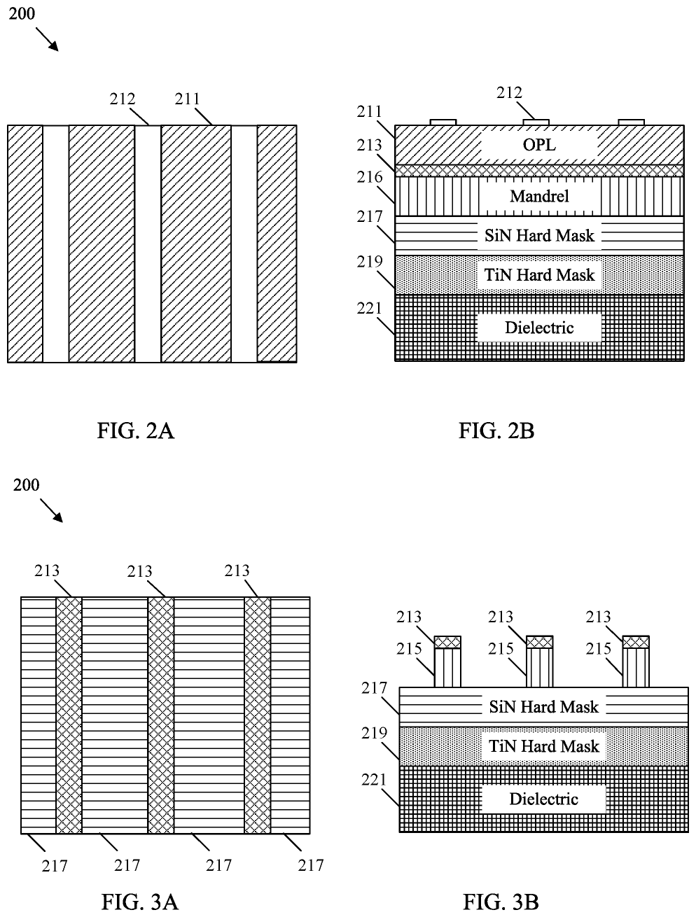

FIGS. 2A-2B are a top view and a side view, respectively of a substrate including a film stack during an example manufacturing process 200. Specifically, the example manufacturing process 200, as depicted in FIGS. 2A-13B, is an example embodiment of an SALEDP process, and can be employed to create a sea of wires including mandrel lines 105 and non-mandrel lines 107 on a substrate 101 as discussed with respect to FIGS. 1A-1B.

The manufacturing process 200 is a process of preparing a wafer to create a sea of metal wires for use in coupling circuit components. The manufacturing process 200 begins by creating a film stack on a wafer. A dielectric 221 is employed as a substrate. The dielectric 221 ultimately serves as a bed for the sea of wires. Hence, the dielectric 221 is an insulator that prevents shorts between the wires positioned in the mandrel and non-mandrel lines. The dielectric 221 may be selected to employ a low dielectric constant (k), such as a k of less than 3.0. A TiN hard mask 219 is positioned onto the dielectric 221, and a SiN hard mask 217 is positioned onto the TiN hard mask 219. The TiN hard mask 219 is a hard material and is employed to resist erosion during the etching processes. For example, the TiN hard mask 219 helps ensure that etches occur in predefined locations and do not drift toward locations of neighboring components, which can cause electrical shorts. The SiN hard mask 217 can be selectively etched by some etching processes and can resist other etching processes. Hence, the SiN hard mask 217 supports etching control during the manufacturing process 200.

A mandrel layer 216 is deposited onto the SiN hard mask 217. The mandrel layer 216 may include an organic planarization layer (OPL) of material. Such organic material can be deposited to create a planarized (e.g., flat) surface to support consistent lithography. The mandrel layer 216 provides a material that can be etched into mandrel lines. An oxide film 213 is positioned onto the mandrel layer 216. The oxide film 213 is a thin film, and may be deposited via in-situ radical assisted deposition (IRAD). The oxide film 213 is optional, and may be employed to support selective etching of OPL material at a later portion of the manufacturing process 200. A OPL layer 211 is also deposited onto the oxide film 213. The OPL layer 211 provides a planar surface for accepting a mandrel mask 212. The mandrel mask 212 is a lithographic hard mask, such as an EUV mask. The mandrel mask 212 covers areas designated to become mandrel lines and exposes areas to be etched away to reveal the mandrel lines. As shown in FIG. 2A, the top view of the substrate shows the OPL layer 211 covered in a mandrel mask 212, while a side view in FIG. 2B shows the film stack as described above.

FIGS. 3A-3B are a top view and a side view, respectively, of the substrate after lithographic etching via a mandrel pattern mask during the example manufacturing process 200. Specifically, an etching process is applied to the mandrel mask 212, and the mandrel mask 212 is removed to result in FIGS. 3A-3B. The etching process may be a dry etching process. For example, the film stack can be covered by the mandrel mask 212, a plasma reactive gas can be applied, and a laser can be employed to ionize the gas. The resulting ions etch away the OPL layer 211, the oxide film 213, and the mandrel layer 216 except for areas covered by the mandrel mask 212. The SiN hard mask 217 prevents the etching from going deeper into the substrate. This results in the creation of mandrel lines 215 on the SiN hard mask 217. Additional OPL layer 211 protected by the mandrel hard mask 212 and remaining above the oxide film 213 can also be removed by other processes (e.g., etching), leaving behind the mandrel lines 215 protected by the oxide film 213 as shown. Hence, the etching, via the mandrel mask 212, results in a plurality of mandrel lines 215 etched from the mandrel layer 216. Such mandrel lines 215 are separated by spaces for use later in the manufacturing process 200. In FIG. 3A, the top view of the substrate shows the mandrel lines 215 covered by oxide film 213 and extending across the SiN hard mask 217. The side view 3B depicts the mandrel lines 215 from one side as attached to the SiN hard mask 217 and covered by the oxide film 213.

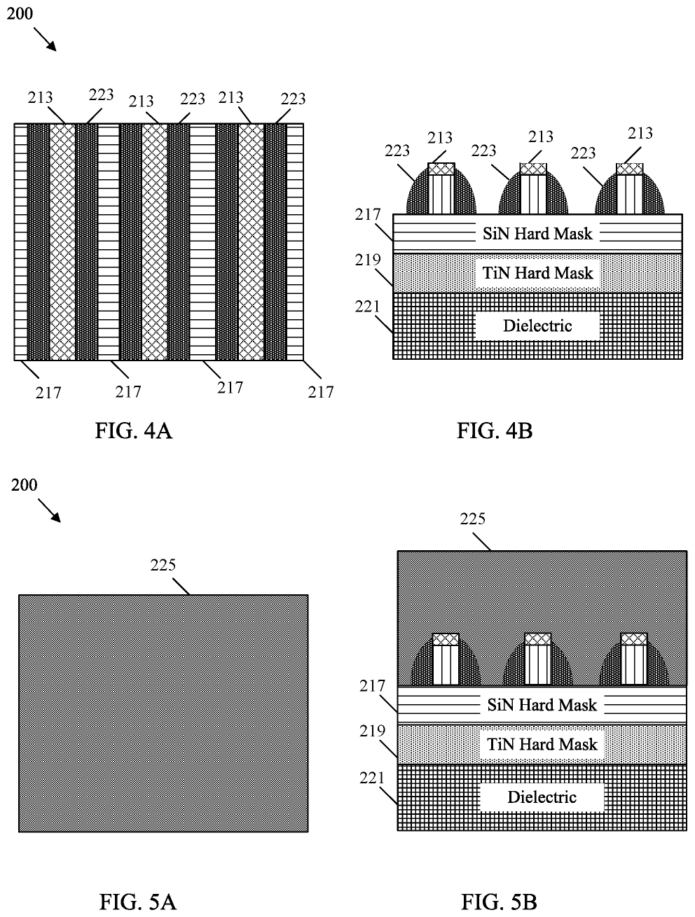

FIGS. 4A-4B are a top view and a side view, respectively, of the substrate after spacer 223 deposition during the example manufacturing process 200. The manufacturing process 200 deposits the spacers 223 around the mandrel lines 215 prior to depositing SOG as shown below. For example, the spacers 223 can be deposited to cover the mandrel lines 215. An etch-back process can then be employed to remove the spacer 223 material above the mandrel lines 215 while leaving the spacer 223 material attached to the side walls of the mandrel lines 215. The etch-back process can include application of an etching material (gas or liquid) for a predetermined time period and/or until the mandrel lines 215 are exposed. The spacers 223 can be employed to guide the deposition of SOG later in the manufacturing process 200 to support etching the non-mandrel lines. For example, spacers 223 can act as a further buffer to mitigate mandrel line 215 to non-mandrel line shorts. In FIG. 4A, the top view of the substrate shows the mandrel lines 215 covered by oxide film 213 and extending across the SiN hard mask 217 and surrounded by spacers 223. The side view 4B depicts the mandrel lines 215 from one side as attached to the SiN hard mask 217, covered by the oxide film 213, with spacers 223 deposited against the sidewalls of the mandrel lines 215.

FIGS. 5A-5B are a top view and a side view, respectively, of the substrate after SOG 225 backfill during the example manufacturing process 200. The manufacturing process 200 deposits SOG 225 to backfill the spaces between the mandrel lines 215. As shown, the SOG 225 covers the SiN hard mask 217 in the open spaces between the spacers 223. The SOG 225 also covers the mandrel lines 215 and oxide film 213. The SOG 225 is a mixture of silicon dioxide (SiO2) and dopants such as boron and/or phosphorus suspended in a solvent solution. The SOG 225 is a low viscosity liquid that can be poured over the substrate. The substrate is spun in order to evenly distribute the SOG 225 across the substrate. The SOG 225 can also be baked to create a solid planar surface. In FIG. 5A, the top view of the substrate shows a solid planar SOG 225 surface. The side view 5B depicts the SOG 225 filling the spaces between the mandrel lines 215 and spacers 223 and covering the SiN hard mask 217.

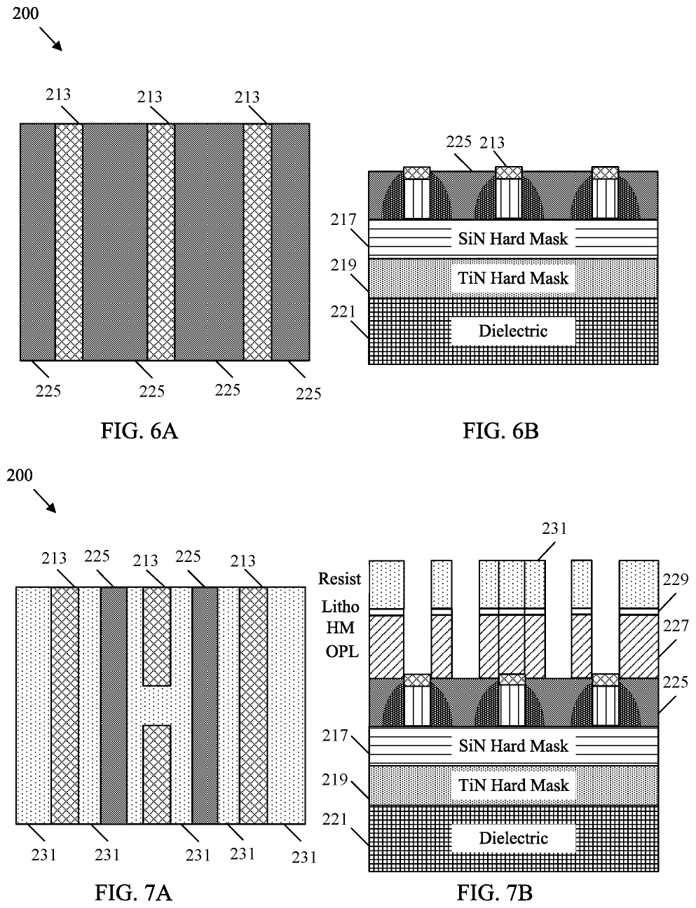

FIGS. 6A-5B are a top view and a side view, respectively, of the substrate after SOG 225 etch-back during the example manufacturing process 200. An etch-back process is performed on the SOG 225 prior to etching the SOG 225 as shown below. The etch-back process is performed to expose the mandrel lines 215. In this case, the oxide film 213 is also exposed. The etch-back process can employ an etching material (dry or wet etching) that is applied to, and reacts with, the SOG 225. The etching material can be allowed to remain on the substrate until a predetermined end point is reached. For example, the etching material can remain on the SOG 225 for a predetermined time or until the mandrel lines 215 are exposed. In FIG. 6A, the top view of the substrate shows a planar SOG 225 surface with oxide film 213 exposed above the SOG 225. The side view 6B depicts the SOG 225 filling the spaces between the mandrel lines 215 and spacers 223 and covering the SiN hard mask 217 at a level that leaves the oxide film 213 and/or a portion of the mandrel lines 215 exposed.

FIGS. 7A-7B are a top view and a side view, respectively, of the substrate after lithographic etching via a non-mandrel pattern mask during the example manufacturing process. The manufacturing process 200 deposits an OPL layer 227 over the SOG 225 to provide a planar etching surface. The OPL layer 227 may be substantially similar to OPL layer 211. A non-mandrel mask 229 is placed on the OPL layer 227. The non-mandrel mask 229 is a lithographic hard mask, such as an EUV. The non-mandrel mask 229 may be substantially similar to the mandrel mask 212, but may contain openings for areas to be etched out in order to create non-mandrel lines. A photo-resist 231 can also be employed. A photo-resist 231 is a compound that is resistant to a developer solution in the absence of light (e.g., EUV light), but can be etched by the developer solution after exposure to the light. For example, the photo-resist 231 can be deposited and spun onto the substrate and baked. Light can then be applied to the photo-resist 231 to create a pattern for the non-mandrel mask 229. The developer solution can then be applied to etch the shape of the non-mandrel lines into the photo-resist 231. The non-mandrel line shapes can then be etched into the non-mandrel mask 229 via the openings in the photo-resist 231 and into the OPL layer 227 via the resulting openings in the non-mandrel mask 229 by subsequent etching materials. It should be noted that the mandrel mask 212 in FIGS. 2A-2B can be employed to etch the mandrel lines 215 in a similar fashion. In the present example, the non-mandrel mask 229 is employed to etch down to the SOG in locations that are designated to become non-mandrel lines. The non-mandrel mask 229 is also employed to etch down to the oxide film 213 covering the mandrel lines 215. The non-mandrel mask 229 also covers any designated gaps in the mandrel lines 215. This ensures that the mandrel lines 215 are etched into the dielectric 221 substrate at a later point in the manufacturing process 200, while the gaps in the mandrel lines 215, as covered by the non-mandrel mask 229, are not etched into the dielectric 221. Hence, in manufacturing process 200, gaps are created in the mandrel lines 215 by the non-mandrel mask 229. In FIG. 7A, the top view of the substrate depicts the SOG 225 surface and oxide film 213 in areas designated to become non-mandrel and mandrel lines, respectively. The side view 7B depicts the photo-resist 231, the non-mandrel mask 229, and the OPL layer 227 etched down to expose surfaces for etching the non-mandrel and mandrel lines.

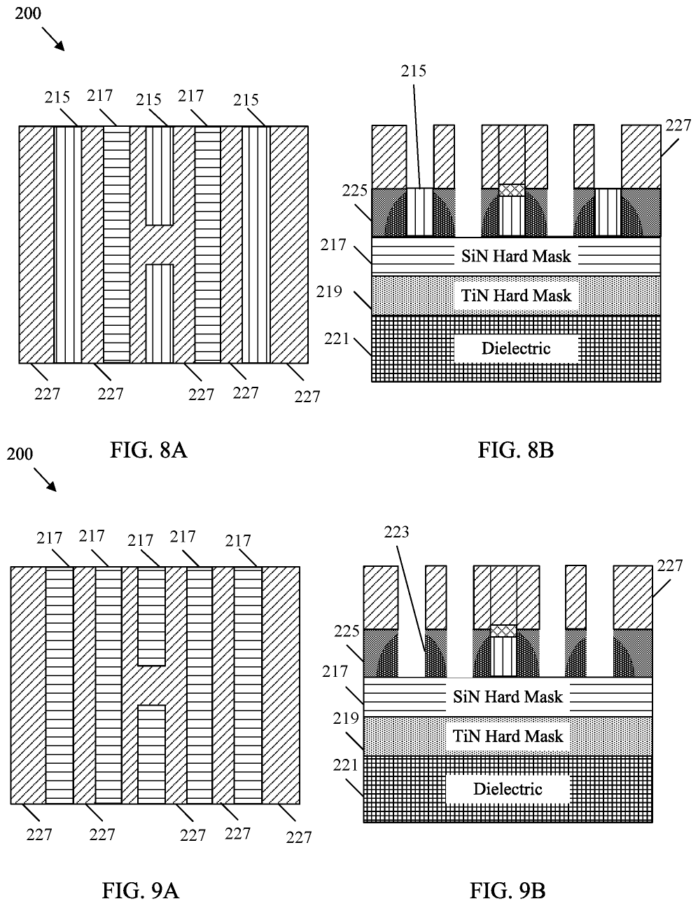

FIGS. 8A-8B are a top view and a side view, respectively, of the substrate after non-mandrel removal during the example manufacturing process 200. For example, the photo-resist 231 and the non-mandrel mask 229 are removed (e.g., etched away). Further, an etching material can also be applied that does not react to the OPL layer 227, but does react to the oxide film 213 and the SOG 225. The mandrel lines 215 remain as the mandrel lines 215 are made of OPL. However, the oxide film 213 and the SOG 225 are removed from openings in the OPL layer 227 as created by the non-mandrel mask 229. Hence, the non-mandrel mask 229 creates holes for etching the SOG 225 from the spaces between the mandrel lines 215 to create non-mandrel lines. As the non-mandrel lines are etched directly into the SOG 225, any gaps in the non-mandrel lines can be created by covering such portions of the OPL layer 227 with the non-mandrel mask 229. Hence, the non-mandrel mask 229 creates any desired gaps in both the mandrel lines 215 and the non-mandrel lines. In FIG. 8A, the top view of the substrate depicts exposed mandrel lines 215 for further etching with gaps in the mandrel lines 215 covered by the OPL 227 layer. The non-mandrel lines are etched through the SOG 225, revealing the SiN hard mask 217 underneath. The side view 8B depicts mandrel lines 215 exposed by the OPL latey 227 and non-mandrel lines etched to the SiN hard mask 217 due to etching away the SOG 225 in such locations.

FIGS. 9A-9B are a top view and a side view, respectively, of the substrate after mandrel line 215 removal during the example manufacturing process 200. Exposed mandrel line 215 material is removed, for example by employing plasma reactive gas and a laser to selectively etch away the mandrel line 215 material. This results in etching down to the SiN hard mask 217 in locations where the mandrel line 215 material is exposed by the OPL 227 layer. At this point, the final mandrel lines and non-mandrel lines are present in the form of exposed SiN hard mask 217, while gaps in the lines and spaces between the lines are present in the form of OPL layer 227 coverings. In FIG. 9A, the top view of the substrate depicts mandrel lines and non-mandrel lines as exposed SiN hard mask 217 surrounded by OPL layer 227 in locations that are not designated to contain a portion of the sea of wires. The side view 9B depicts openings in the OPL latey 227, SOG 225 layer, and spacers 223 as the mandrel and non-mandrel lines.

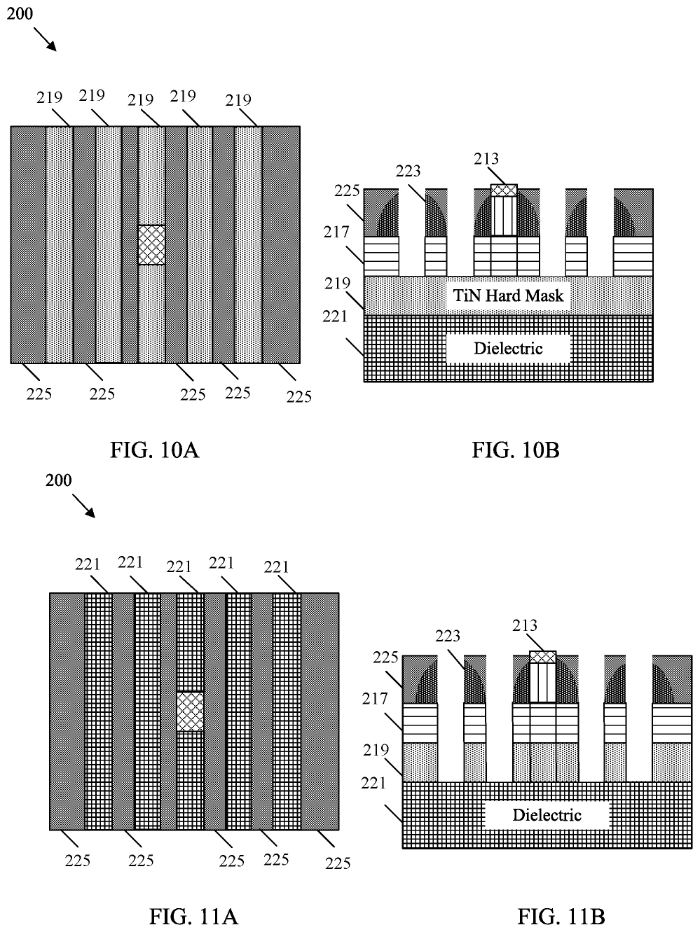

FIGS. 10A-10B are a top view and a side view, respectively, of the substrate after SiN hard mask 217 etching during the example manufacturing process 200. An etching material that reacts with the SiN hard mask 217 and the OPL layer 227 layer but not the oxide film 213 and the SOG 225 is applied to the substrate. This removes the OPL layer 227 and etches the mandrel lines and non-mandrel lines into the SiN hard mask 217. Any gaps in the mandrel lines are maintained from etching by the oxide film 213 and any gaps in the non-mandrel lines are maintained by the SOG 225. Hence, the mandrel lines and non-mandrel lines are etched until the TiN hard mask 219 is exposed. In FIG. 10A, the top view of the substrate depicts mandrel lines and non-mandrel lines as exposed TiN hard mask 219 surrounded by SOG 225, with mandrel line gaps protected from the etching by the oxide film 213 and non-mandrel line gaps protected by the SOG 225. The side view 10B depicts openings in the SOG 225 layer, spacers 223, and SiN hard mask 217 as the mandrel and non-mandrel lines.

FIGS. 11A-11B are a top view and a side view, respectively, of the substrate after TiN hard mask 219 etching during the example manufacturing process 200. An etching material that reacts with the TiN hard mask 219, but not the oxide film 213 and the SOG 225 is applied to the substrate. This etches the mandrel lines and non-mandrel lines through the TiN hard mask 219 and down to the dielectric 221. Gaps in the mandrel lines are protected from etching by the oxide film 213 and gaps in the non-mandrel lines are protected from etching by the SOG 225. In FIG. 11A, the top view of the substrate depicts mandrel lines and non-mandrel lines as exposed dielectric 221 surrounded by SOG 225, with mandrel line gaps protected from the etching by the oxide film 213 and non-mandrel line gaps protected by the SOG 225. The side view 11B depicts openings in the SOG 225 layer, spacers 223, SiN hard mask 217, and TiN hard mask 219 as the mandrel and non-mandrel lines.

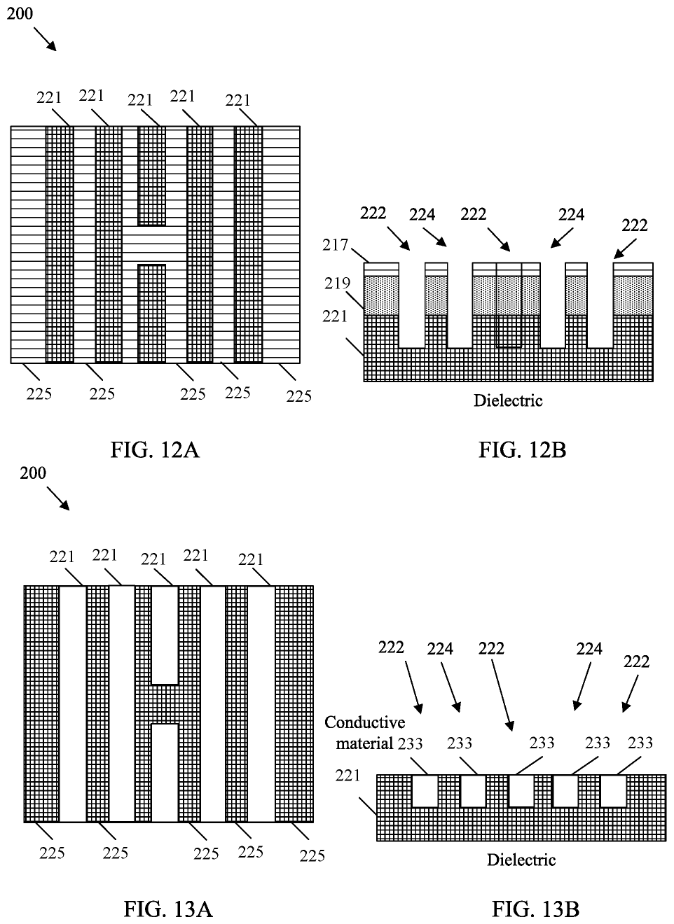

FIGS. 12A-12B are a top view and a side view, respectively, of the substrate after dielectric 221 etching during the example manufacturing process 200. An etching material that is applied to the substrate to etch away the SOG 225, spacers 223, and oxide film 213 as well as any remaining mandrel line 215 material protected by the oxide film. The etching material etches mandrel line channels 222 and non-mandrel line channels 224 in the dielectric based on openings in the SiN hard mask 217 and TiN hard mask 219. Gaps in the mandrel line channels 222 and non-mandrel line channels 23 are preserved by the SiN hard mask 217 and TiN hard mask 219. The etching material may be employed until an end point is reached (e.g., a time duration) to create an expected depth for the sea of wires in the dielectric 221. The etching material may also etch away some portion of the SiN hard mask 217, but may not reach/extend into the TiN hard mask 219. At this point, the mandrel line channels 222 and non-mandrel line channels 224 are present in their final locations in the dielectric 221. In FIG. 12A, the top view of the substrate depicts mandrel line channels 222 and non-mandrel line channels 223 as exposed dielectric 221 surrounded by SiN hard mask 217. The side view 12B depicts openings in the SiN hard mask 217, TiN hard mask 219, and dielectric 221 as the mandrel line channels 222 and non-mandrel line channels 224.

FIGS. 13A-13B are a top view and a side view, respectively, of the substrate after metallization during the example manufacturing process 200. The SiN hard mask 217 and TiN hard mask 219 are removed from the dielectric 221, for example by an etching material that reacts with SiN hard mask 217 and TiN hard mask 219 but not dielectric 221. The etched areas in the dielectric 221 contain the final mandrel line channels 222 and non-mandrel line channels 224. Hence, conductive material 233, such as metal (e.g., copper, gold, etc.), is poured into the etched areas in the dielectric 221 and allowed to dry. Replacing the mandrel line channels 222 and the non-mandrel line channels 224 in the dielectric 221 with conductive material 233 results in a sea of wires with gaps at predetermined positions. This manufacturing process 200 omits metal 233 from desired portions of the mandrel line channels 222 and the non-mandrel line channels 224. Hence, dummy lines/traces are not included and parasitic capacitance is reduced. Further, the process employs only two EUV masks (mandrel mask and non-mandrel mask). In addition, etching the non-mandrel lines in the SOG 225 allows for independent mandrel line channel 222 and non-mandrel line channel 224 length and position as well as mitigating shorts.

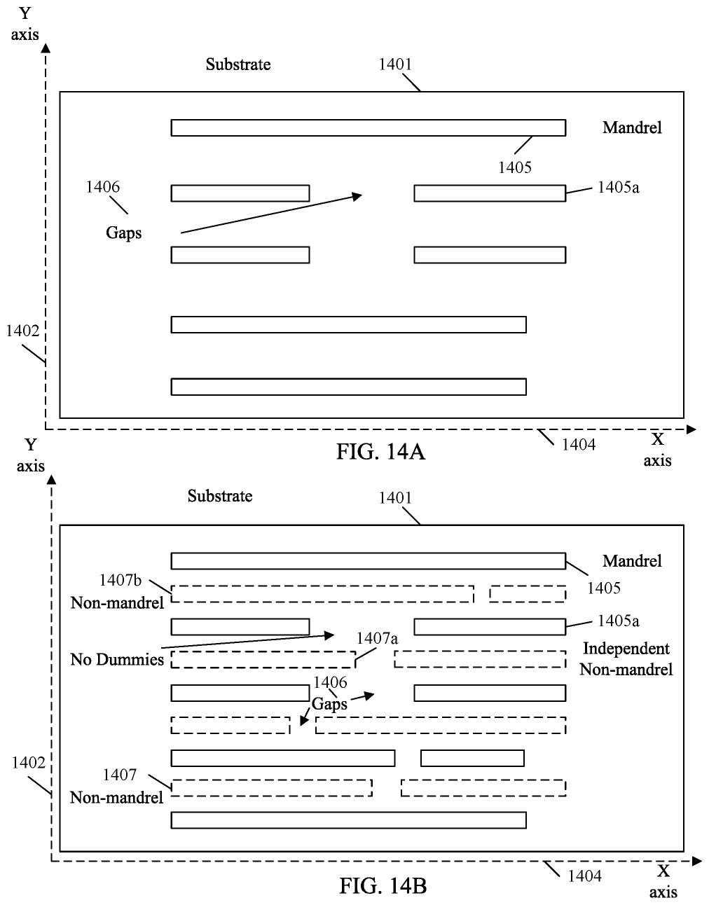

FIG. 14A is a top view of a second example substrate 1401 including mandrel lines 1405 upon application of a mandrel pattern mask. Substrate 1401 contains mandrel lines 1405 with lengths along an X axis 1404 and widths along a Y axis 1402, which are similar to substrate 101, mandrel lines 105, X axis 104, and Y axis 102, respectively. The difference between substrate 101 and substrate 1401 is that mandrel lines 105 are created by the mandrel mask in continuous segments (with gaps 106 created by the non-mandrel mask). In contrast, in substrate 1401 gaps 1406 are etched in the mandrel lines 1405 by the mandrel mask prior to creating the non-mandrel lines. Specifically, the mandrel lines 1405 are initially etched with the gaps 1406 instead of creating them later in the process with the non-mandrel mask. The functionality of gaps 1406 are otherwise substantially similar to gaps 106. Hence, mandrel line 1405a is created with a gap 1406 and without a space for a dummy trace by the mandrel mask.

FIG. 14B is a top view of the second example substrate 1401 including mandrel lines 1405 and non-mandrel lines 1407 upon application of a non-mandrel pattern mask. Non-mandrel lines 1407 are substantially similar to non-mandrel lines 107. As with non-mandrel lines 107, non-mandrel lines 1407 have lengths and positions along the X axis 1404 that are independent of the lengths and positions along the X axis 1404 of the mandrel lines 1405. Further, non-mandrel lines 1407 can extend past gaps 1406 in adjacent mandrel lines 1405. For example, mandrel lines 1405a contains a gap 1406 created by the mandrel mask. Because non-mandrel lines 1407 are etched into SOG, the non-mandrel line 1407a can extend past the gap 1406 in mandrel line 1405a along the X axis 1404. It should be noted that an SADP process employs mandrel lines to shape non-mandrel lines. Hence, in an SADP process the non-mandrel line 1407a would not be shaped properly by the spacer around the mandrel line 1405a. Accordingly, in an SADP process, the material for the non-mandrel line 1407a would flow through the gap 1406 between portions of the mandrel line 1405a and short with the non-mandrel line 1407b. As such, the SALEDP process allows for mandrel lines 1405 to be created with gaps 1406 by the mandrel mask without altering the adjacent non-mandrel lines 1407, which is not possible in an SADP process. The following FIGS. are substantially similar to FIGS. 2A-13B, but describe the example where mandrel lines 1405 are created with gaps 1406 by the mandrel mask instead of adding gaps to the mandrel lines 1405 by the non-mandrel mask later in the process. The resulting substrate from either process may be substantially similar.

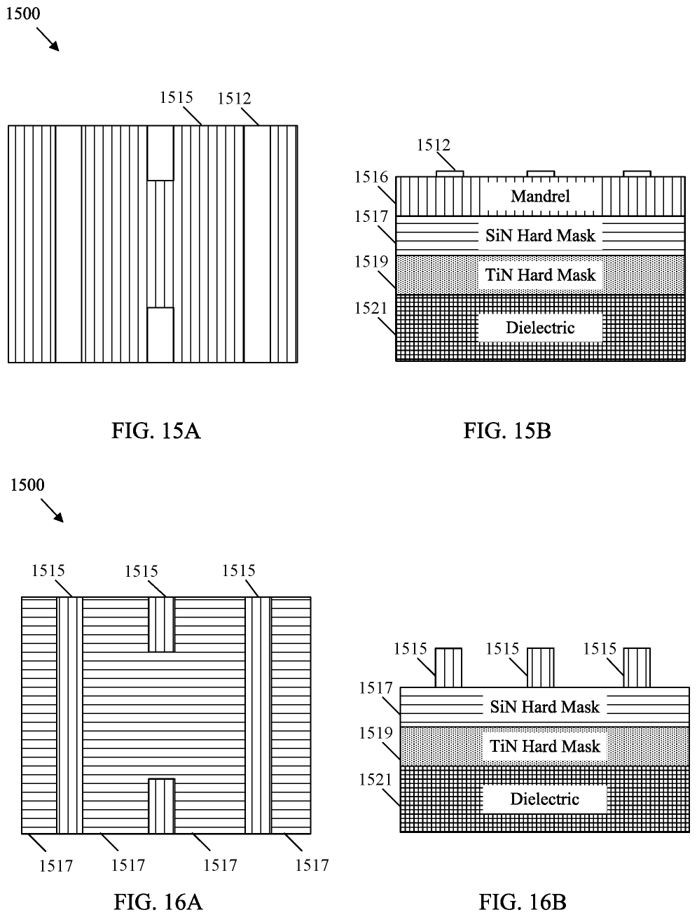

FIGS. 15A-15B are a top view and a side view, respectively of a substrate including a film stack during a second example manufacturing process 1500. The substrate includes a mandrel mask 1512, a mandrel layer 1516, a SiN hard mask 1517, a TiN hard mask 1519, and a dielectric 1521, which are substantially similar to mandrel mask 212, mandrel layer 216, SiN hard mask 217, TiN hard mask 219, and dielectric 221, respectively. Manufacturing process 1500 may not employ an oxide film. Further, the mandrel mask 212 contains a gap for creating a gap in the lines created from the mandrel layer 215 during etching. The substrate of manufacturing process 1500 is otherwise similar to manufacturing process 200.

FIGS. 16A-16B are a top view and a side view, respectively, of the substrate after lithographic etching via the mandrel mask 1512 during the second example manufacturing process 1500. As shown, etching material is applied to the mandrel mask 1512 to etch the mandrel layer 1516 into mandrel lines 1515, and the mandrel mask 1512 is removed. This leaves mandrel lines 1515 attached to the SiN hard mask 1517 with gap(s) in predetermined locations. The top view of FIG. 16A shows the mandrel lines 1515, with a gap in a mandrel line 1515, on the SiN hard mask 1517 surface, and the side view 16B shows the mandrel lines 1515 on the SiN hard mask 1517.

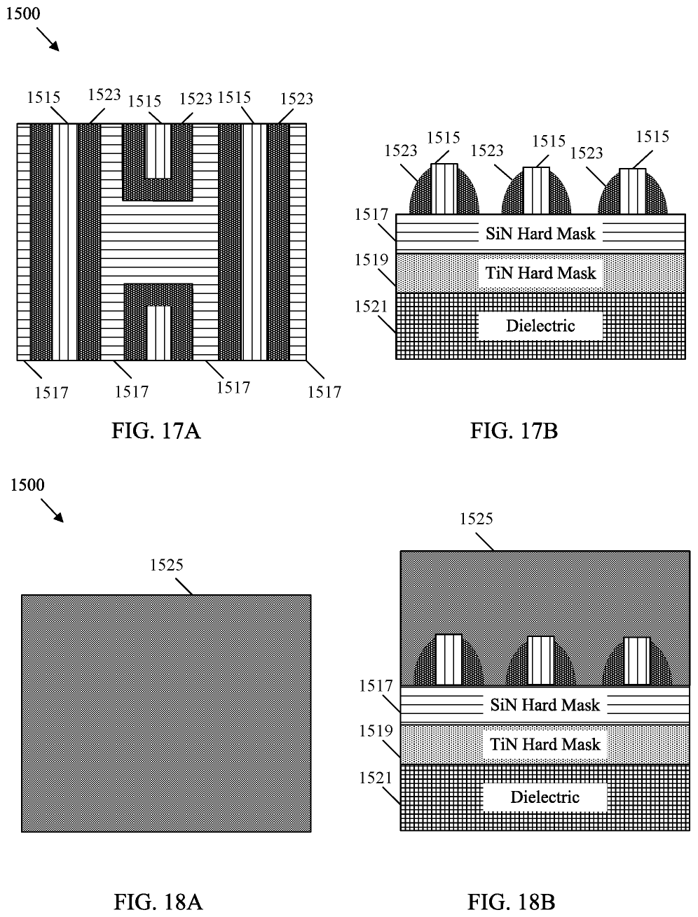

FIGS. 17A-17B are a top view and a side view, respectively, of the substrate after spacer 1523 deposition during the second example manufacturing process 1500. The spacer 1523 is substantially similar to spacer 223. The spacer 1523 surrounds the mandrel lines 1515, and further extends into the gap in the mandrel line 1515. This ensures that the spacer 1523 completely surrounds the mandrel lines 1515. FIGS. 17A-17B both show the mandrel lines 1515 surrounded by spacer 1523 and positioned on the SiN hard mask 1517 surface.

FIGS. 18A-18B are a top view and a side view, respectively, of the substrate after SOG 1525 backfill during the second example manufacturing process 1500. The SOG 1525 is substantially similar to SOG 225, and fills in the spaces on the surface of the SiN hard mask 1517 between mandrel lines 1515 and spacers 1523 in the same manner as in FIGS. 5A-5B in manufacturing process 200.

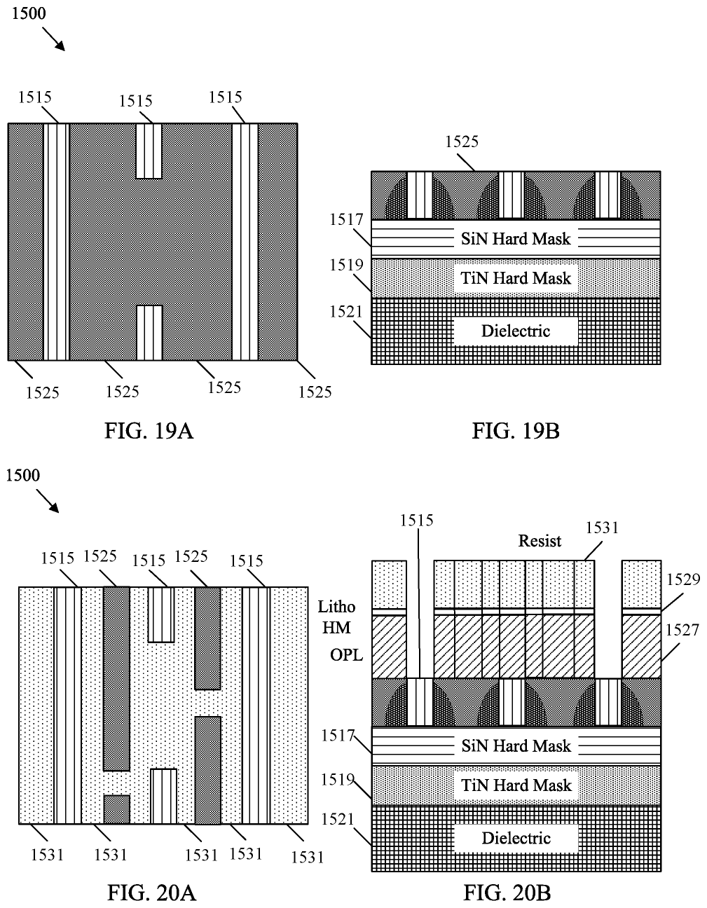

FIGS. 19A-19B are a top view and a side view, respectively, of the substrate after SOG 1525 etch-back during the second example manufacturing process 1500. The SOG 1525 is etched down to expose the mandrel lines 1515 in a manner similar to the etch-back process described in FIGS. 6A-6B in manufacturing process 200.

FIGS. 20A-20B are a top view and a side view, respectively, of the substrate after lithographic etching via a non-mandrel mask 1529 during the second example manufacturing process 1500. An OPL layer 1527, non-mandrel mask 1529, and photo-resist 1531, which are substantially similar to OPL layer 227, non-mandrel mask 229, and photo-resist 231, respectively, are added to the substrate as discussed with respect to FIGS. 7A-7B for manufacturing process 200. The difference is that the gaps in the mandrel lines 1515 already exist. The non-mandrel mask 1529 exposes both the mandrel lines 1515 and SOG 1525 in the spaces between the mandrel lines 1515 where the non-mandrel lines are to be positioned. The exposure of the etching material may be timed to etch through the OPL layer 1527 in order to expose both the SOG 1525 and the mandrel lines 1515. FIG. 20A shows the photo-resist 1531 covering everything but the mandrel lines 1515 and the SOG 1525 in the position designated for the non-mandrel lines. FIG. 20B shows the photo-resist 1531, non-mandrel mask 1529, and OPL layer 1527 positioned above the remainder of the substrate.

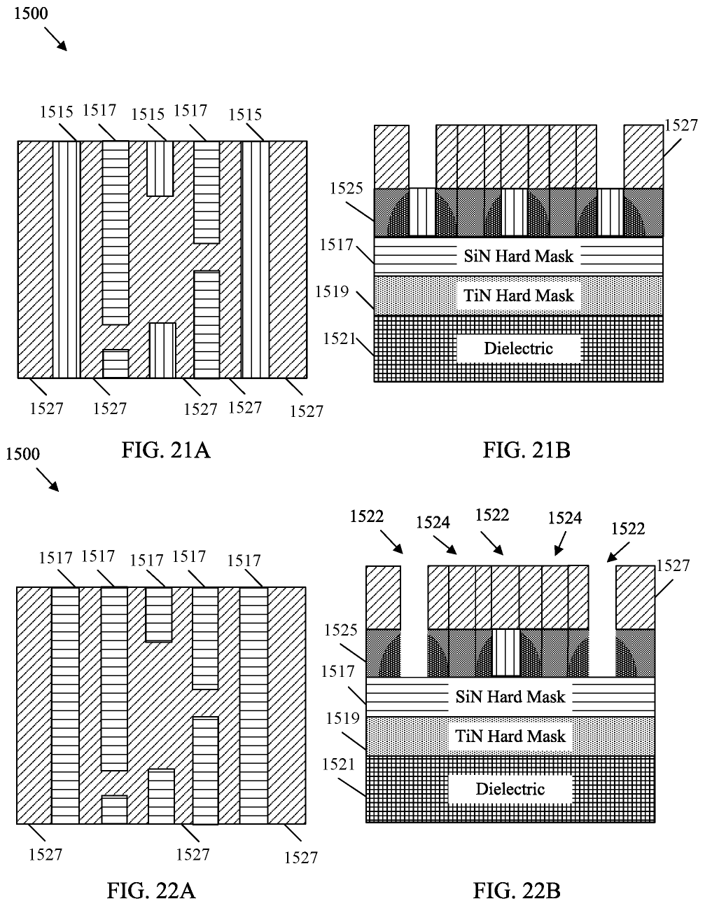

FIGS. 21A-21B are a top view and a side view, respectively, of the substrate after non-mandrel removal during the second example manufacturing process 1500. The substrate is exposed to an etching material that reacts with the SOG 1525, the photo-resist 1531, and the non-mandrel mask 1529, but not the OPL in the mandrel line 1515 and the OPL layer 1527. Accordingly, the non-mandrel lines are etched from the SOG 1525 down to the SiN hard mask 1517. Further, the photo-resist 1531 and the non-mandrel mask 1529 are etched away, leaving the OPL layer 1527 and the mandrel lines 1515. As such, FIG. 21A shows the mandrel lines 1515 and the shape of the non-mandrel lines etched down to the SiN hard mask 1517 and into the OPL layer 1527. FIG. 21B shows the OPL layer 1527 attached to the SOG 1525 with non-mandrel openings in the SOG 1525 down to the SiN hard mask 1517.

FIGS. 22A-22B are a top view and a side view, respectively, of the substrate after mandrel line 1515 removal during the second example manufacturing process 1500. The mandrel line 1515 is removed, for example by employing a laser and a plasma reactive gas. This results in etching the mandrel lines down to the SiN hard mask 1517. FIG. 22A shows the shape of the mandrel lines and non-mandrel lines etched down to the SiN hard mask 1517 and into the OPL layer 1527. FIG. 22B shows the OPL layer 1527 attached to the SOG 1525 with mandrel line channels 1522 and non-mandrel line channels 1524 in the SOG 1525 down to the SiN hard mask 1517.

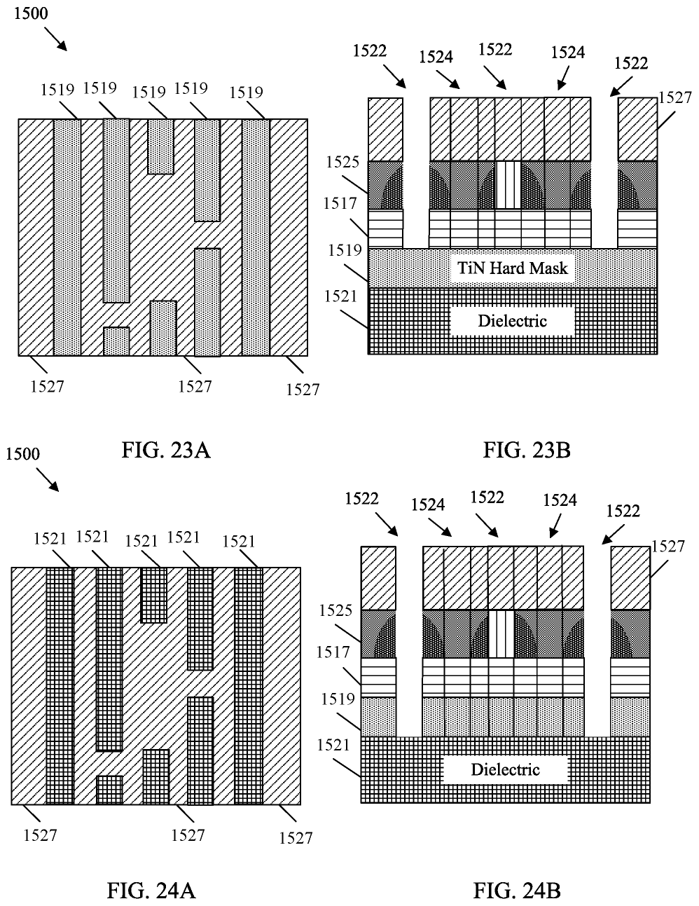

FIGS. 23A-23B are a top view and a side view, respectively, of the substrate after SiN hard mask 1517 etching during the second example manufacturing process 1500. An etching material that reacts with the SiN hard mask 1517 and not the TiN hard mask 1519 is applied to the substrate. This etches the mandrel line channels 1522 and the non-mandrel line channels 1524 through the SiN hard mask 1517 and down to the TiN hard mask 1519. FIG. 23A shows the shape of the mandrel lines and non-mandrel lines etched down to the TiN hard mask 1519 in the OPL layer 1527. FIG. 23B shows the OPL layer 1527 attached to the SOG 1525 with mandrel line channels 1522 and non-mandrel line channels 1524 through the SOG 1525 and the SiN hard mask 1517 down to the TiN hard mask 1519.

FIGS. 24A-24B are a top view and a side view, respectively, of the substrate after TiN hard mask 1519 etching during the second example manufacturing process 1500. An etching material that reacts with the TiN hard mask 1519 is applied to the substrate. This etches the mandrel line channels 1522 and the non-mandrel line channels 1524 through the TiN hard mask 1519 and down to the dielectric. FIG. 24A shows the shape of the mandrel lines and non-mandrel lines etched down to the dielectric 1521 and into the OPL layer 1527. FIG. 24B shows mandrel line channels 1522 and non-mandrel line channels 1524 through the SOG 1525, the SiN hard mask 1517, the TiN hard mask 1519, and down to the dielectric 1521.

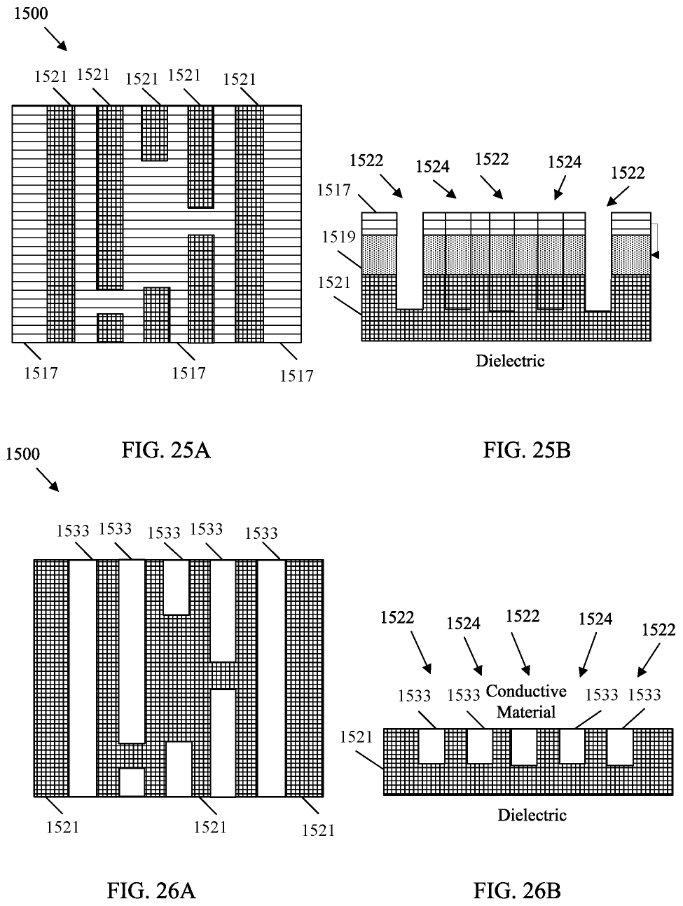

FIGS. 25A-25B are a top view and a side view, respectively, of the substrate after dielectric 1521 etching during the second example manufacturing process 1500. An etching material is applied to etch the mandrel lines and non-mandrel lines into the dielectric 1521. This etching material also removes the OPL layer 1527, the SOG 1525, and the spacers 1523, as well as etching away some of the SiN hard mask 1517. FIG. 25A shows the shape of the mandrel lines and non-mandrel lines etched down to the dielectric 1521 and into the SiN hard mask 1517. FIG. 25B shows mandrel line channels 1522 and non-mandrel line channels 1524 etched through the SiN hard mask 1517, the TiN hard mask 1519, and into to the dielectric 1521.

FIGS. 26A-26B are a top view and a side view, respectively, of the substrate after metallization during the second example manufacturing process 1500. An etching material is applied to remove the SiN hard mask 1517 and the TiN hard mask 1519, which leaves the dielectric 1521 including the mandrel lines and the non-mandrel lines. Conductive material 1533 can then be added to the mandrel lines and non-mandrel lines in a manner substantially similar to the process discussed with respect to FIGS. 13A-13B. Such conductive material 1533 may be substantially similar to conductive material 233. Hence, FIGS. 26A-26B show the dielectric 1521 including conductive material 1533 in the shapes of the predetermined mandrel lines and non-mandrel lines.

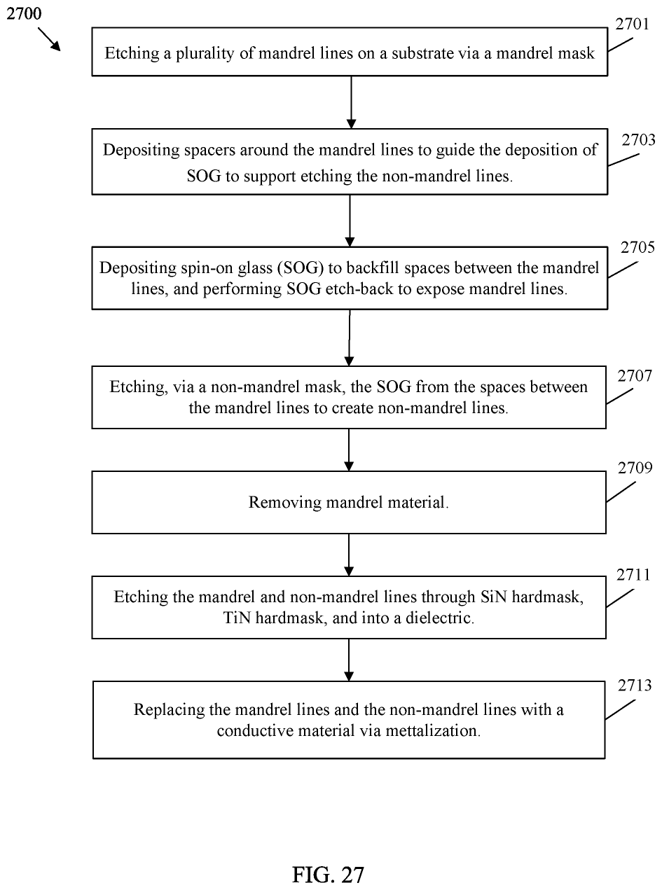

FIG. 27 is a flowchart of an example method 2700 of manufacturing a wafer, such as substrate 101 and/or substrate 1401 in accordance with various embodiments, such as manufacturing process 200 and/or 1500.

At block 2701, a plurality of mandrel lines are etched on the substrate via a mandrel mask. Spaces are maintained between the mandrel lines in order to separate the mandrel lines and define a position for non-mandrel lines. For example, the mandrel lines can extend across the wafer/substrate along a first axis with spaces positioned along a second axis perpendicular to the first axis. The mandrel lines may be etched by a mandrel mask. In some example (e.g., manufacturing process 1500), gaps can be created in the mandrel lines along the first axis by employing the mandrel mask prior to creating the non-mandrel lines. In other examples (e.g., manufacturing process 200), the mandrel lines are created by the mandrel mask as solid lines extending across the first axis with no gaps.

At block 2703, spacers are deposited around the mandrel lines. This is accomplished prior to depositing SOG in block 2705. The spacers can later be employed to guide the deposition of the SOG to support etching the non-mandrel lines. The spacers surround the mandrel lines and may extend through gaps in the mandrel lines when such gaps are created by the mandrel mask.

At block 2705, SOG is deposited to backfill the spaces between the mandrel lines. When gaps in the mandrel lines are created by the mandrel mask, the SOG can extend into such gaps. An etch-back can also be performed on the SOG prior to etching the SOG. This can expose at least some of the mandrel lines for further etching. Gaps in the mandrel lines, when created by a mandrel mask, can remain covered by the SOG to prevent such gaps from being etched into the mandrel lines.

At block 2707, a non-mandrel mask is employed to etch the SOG from the spaces between the mandrel lines to create non-mandrel lines. In some examples (e.g., manufacturing process 200), and designated gaps in the mandrel lines can be created by the non-mandrel mask. The non-mandrel mask can also be employed to create non-mandrel lines in the SOG that omit dummy traces. Such non-mandrel lines extend along the first axis, and may contain a length and position along the first axis that is independent of a length and position of mandrel lines along the first axis. This can be accomplished because the non-mandrel lines are etched into the SOG instead of positioned solely by the spacers around the mandrel lines. In some examples, the mandrel lines and the non-mandrel lines can include a width along the second axis of eighty nm or less (e.g., fourteen nm, ten nm, seven nm, etc.). For example, the mandrel lines and the non-mandrel lines can be created according to a fourteen nm process, a ten nm process, a seven nm process, etc.

At block 2709, the mandrel and material is removed, which creates openings for the mandrel lines and the non-mandrel lines. This effectively creates a mask for further etching. Such openings can then be employed to etch the mandrel lines and the non-mandrel lines through a SiN hard mask, a TiN hard mask, and into a dielectric at block 2711.

At block 2713, the etched mandrel lines and the etched non-mandrel lines are replaced by filling such lines with a conductive material via metallization. This results in a final substrate containing conductive material in the predetermined locations for mandrel lined and non-mandrel lines. Such lines contain gaps in predefined locations, and hence omit dummy traces. Further, the non-mandrel lines can be independent of the mandrel lines along the first axis.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

Certain terms are used throughout the following description and claims to refer to particular system components. As one skilled in the art will appreciate, different companies may refer to a component by different names. This document does not intend to distinguish between components that differ in name but not function. In the following discussion and in the claims, the terms “including” and “comprising” are used in an open-ended fashion, and thus should be interpreted to mean “including, but not limited to. . . . ” Also, the term “couple” or “couples” is intended to mean either an indirect or direct wired or wireless connection. Thus, if a first device couples to a second device, that connection may be through a direct connection or through an indirect connection via other intervening devices and/or connections. Unless otherwise stated, “about,” “approximately,” or “substantially” preceding a value means +/−10 percent of the stated value or reference.

What is claimed is:

1. A wafer prepared by a process comprising:
etching a plurality of mandrel lines via a mandrel mask, the mandrel lines separated by spaces;
depositing spin-on glass (SOG) to backfill the spaces between the mandrel lines;
etching, via a non-mandrel mask, the SOG from the spaces between the mandrel lines to create non-mandrel lines; and
replacing the mandrel lines and the non-mandrel lines with a conductive material.

2. The wafer of claim 1, wherein the process further comprises depositing spacers around the mandrel lines prior to depositing the SOG, and wherein the spacers guide the deposition of the SOG to support etching the non-mandrel lines.

3. The wafer of claim 1, wherein the non-mandrel lines and the mandrel lines extend across the wafer along a first axis, and wherein lengths and positions of the non-mandrel lines along the first axis is independent of lengths and positions of mandrel lines along the first axis.

4. The wafer of claim 1, wherein etching the SOG via the non-mandrel mask creates non-mandrel lines that omit dummy traces.

5. The wafer of claim 1, wherein the process further comprises performing an etch-back on the SOG, prior to etching the SOG, to expose at least some of the mandrel lines.

6. The wafer of claim 1, wherein gaps are created in the mandrel lines by the non-mandrel mask.

7. The wafer of claim 1, wherein gaps are created in the mandrel lines by the mandrel mask prior to creating the non-mandrel lines.

8. The wafer of claim 1, wherein the mandrel lines and the non-mandrel lines include a width along a second axis of eighty nanometers or less.

9. A method comprising:
etching a plurality of mandrel lines via a mandrel mask, the mandrel lines separated by a space;
depositing spin-on glass (SOG) to backfill the spaces between the mandrel lines;
etching, via a non-mandrel mask, the SOG from the spaces between the mandrel lines to create non-mandrel lines; and
replacing the mandrel lines and the non-mandrel lines with a conductive material.

10. The method of claim 9, further comprising depositing spacers around the mandrel lines prior to depositing the SOG, wherein the spacers guide the deposition of the SOG to support etching the non-mandrel lines.

11. The method of claim 9, wherein the non-mandrel lines and the mandrel lines extend across a wafer along a first axis, and wherein a length and position of the non-mandrel lines along the first axis is independent of a length and position of mandrel lines along the first axis.

12. The method of claim 9, wherein etching the SOG via the non-mandrel mask creates non-mandrel lines that omit dummy traces.

13. The method of claim 9, further comprising performing an etch-back on the SOG, prior to etching the SOG, to expose at least some of the mandrel lines.

14. The method of claim 9, wherein gaps are created in the mandrel lines by the non-mandrel mask.

15. The method of claim 9, wherein gaps are created in the mandrel lines by the mandrel mask prior to creating the non-mandrel lines.

16. The method of claim 9, wherein the mandrel lines and the non-mandrel lines include a width along a second axis of eighty nanometers or less.

17. A wafer comprising:
a substrate;
a plurality of mandrel line channels of conductive material extending across the substrate along a first axis, the mandrel line channels separated by spaces along a second axis perpendicular to the first axis; and
a plurality of non-mandrel line channels of conductive material extending across the substrate along the first axis, wherein lengths and positions of the non-mandrel line channels along the first axis is independent of lengths and positions of mandrel lines along the first axis.

18. The wafer of claim 17, wherein the mandrel line channels omit dummy traces uncoupled to operational components.

19. The wafer of claim 17, wherein the non-mandrel line channels omit dummy traces uncoupled to operational components.

20. The wafer of claim 17, wherein the mandrel line channels and the non-mandrel line channels include a width along the second axis of eighty nanometers or less.
